(19) United States
(12) Patent Application Publication
(10) Pub. No.: US 2024/0387175 A1
(43) Pub. Date: Nov. 21, 2024

(54) SEMICONDUCTOR STRUCTURE AND MANUFACTURING METHOD THEREOF

(71) Applicant: Winbond Electronics Corp., Taichung City (TW)

(72) Inventors: Chungchen Hsu, Taichung City (TW); Tsung-Wei Lin, Taichung City (TW); Kun-Che Wu, Taichung City (TW)

(73) Assignee: Winbond Electronics Corp., Taichung City (TW)

(21) Appl. No.: 18/628,824

(22) Filed: Apr. 8, 2024

(30) Foreign Application Priority Data
May 19, 2023 (TW) 112118811

(51) Int. Cl. H01L 21/033; H01L 21/3213

(52) U.S. Cl. CPC H01L 21/0337; H01L 21/32139

(57) ABSTRACT

A semiconductor structure includes a substrate and a target pattern. The target pattern is disposed on the substrate. The top-view pattern of the target pattern includes a main portion and a protruding portion. The main portion and the protruding portion are connected with each other along the long axis of the top-view pattern of the target pattern. The protruding portion is connected to the main portion. The protruding portion includes a first portion located on one side of the long axis. The maximum width of the first portion perpendicular to the long axis is less than half of the maximum width of the main portion.

### CROSS-REFERENCE TO RELATED APPLICATION

This application claims the priority benefit of Taiwan application serial no. 112118811, filed on May 19, 2023. The entirety of the above-mentioned patent application is hereby incorporated by reference herein and made a part of this specification.

### BACKGROUND

### Technical Field

The present disclosure relates to a semiconductor structure and a manufacturing method thereof, and in particular relates to a semiconductor structure using Litho-Etch-Litho-Etch technology and a manufacturing method thereof.

### Description of Related Art

In some semiconductor structure manufacturing processes, material layers are patterned to form target patterns. In order to achieve high pattern density and gradually shrank line width, some known semiconductor structures are fabricated using double patterning techniques, such as Litho-Etch-Litho-Etch (LELE for short). LELE, also known as pitch splitting, which is performed through two separate lithography and etch steps to define the target pattern, thereby doubling the pattern density. In detail, in the early stage of LELE, the layout patterns that could not be produced through a single exposure are disassembled to form two layout patterns with low pattern density, and then made into two masks. Then, two separate exposure steps and two separate etch steps are used to form two rough patterns, which are then combined and superimposed to form the originally required high-density layout pattern.

However, due to the limitations of the lithography process, in the target pattern formed by LELE, a concave contour is very likely to be formed corresponding to the overlapping position of the two rough patterns. When the target pattern is a conductive structure, the concave contour will lead to an increase in contact resistance, and even affect the operation of the semiconductor device. Therefore, how to develop a semiconductor structure capable of producing desired target patterns and its manufacturing method is a goal to be achieved.

### SUMMARY

The present disclosure provides a semiconductor structure and a manufacturing method thereof, which are able to prevent the formed target pattern from having a concave contour as described in the related art.

The present disclosure provides a semiconductor structure, which includes a substrate and a target pattern. The target pattern is disposed on the substrate. The top-view pattern of the target pattern includes a main portion and a protruding portion. The main portion and the protruding portion are connected with each other along the long axis of the top-view pattern of the target pattern. The protruding portion is connected to the main portion. The protruding portion includes a first portion located on one side of the long axis. The maximum width of the first portion perpendicular to the long axis is less than half of the maximum width of the main portion.

The present disclosure provides a manufacturing method of a semiconductor structure, which includes the following steps: providing a substrate; forming a material layer on the substrate; forming a first hard mask pattern on the material layer; forming a second hard mask pattern on the first hard mask pattern, where the top-view pattern of the second hard mask pattern partially overlaps the top-view pattern of the first hard mask pattern; transferring the pattern of the first hard mask pattern and the pattern of the second hard mask pattern to the material layer to form a target pattern, where the top-view pattern of the target pattern includes a main portion and a protruding portion, where the main portion and the protruding portion are connected to each other along the long axis of the top-view pattern of the target pattern, the protruding portion is connected to the main portion, the protruding portion includes a first portion on one side of the long axis, and the maximum width of the first portion perpendicular to the long axis is less than half of the maximum width of the main portion.

Based on the above, in the semiconductor structure and its manufacturing method provided in the present disclosure, the top-view pattern of the target pattern includes a main portion and a protruding portion, and the main portion and the protruding portion are connected with each other along the long axis of the top-view pattern of the target pattern. The protruding portion includes a first portion located on one side of the long axis, and the maximum width of the first portion perpendicular to the long axis is less than half of the maximum width of the main portion. Therefore, by means of the structural design of the target pattern, it is possible to prevent the formed target pattern from having a concave contour as described in the related art, and thus the process margin of the subsequent process may be improved.

### BRIEF DESCRIPTION OF THE DRAWINGS

FIG. 1A to FIG. 1F are partial perspective views of a manufacturing method of a semiconductor structure according to some embodiments of the present disclosure.

FIG. 2A to FIG. 2C are schematic cross-sectional views along the line I-I′ in FIG. 1C to FIG. 1E.

### DESCRIPTION OF THE EMBODIMENTS

The following examples are listed and described in detail with accompanying drawings, but the provided examples are not intended to limit the scope of the present disclosure. In order to facilitate understanding, the same components will be described with the same symbols in the following description. In addition, the drawings are for illustration purposes only and are not drawn to original scale. In fact, the dimensions of the various features may be increased or reduced freely for clarity of discussion.

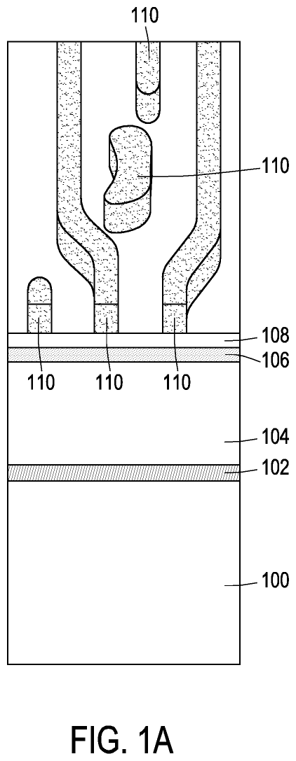

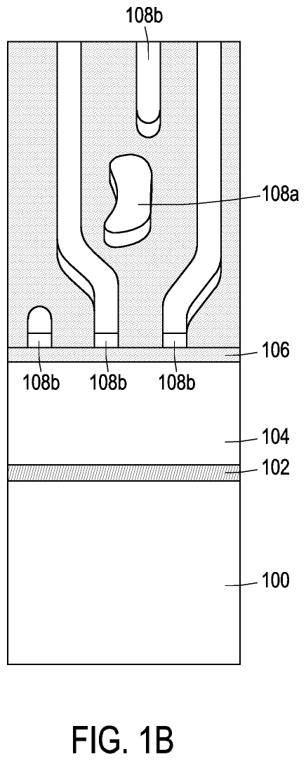

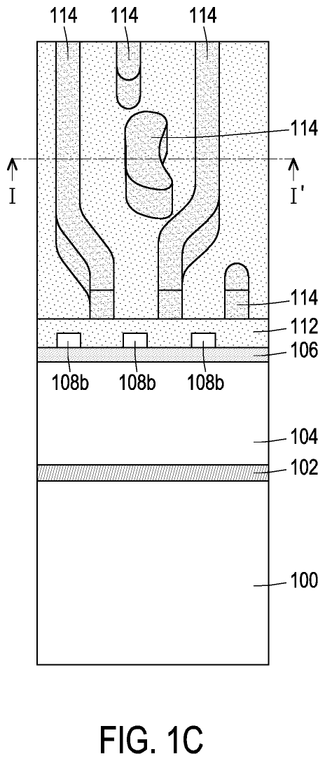

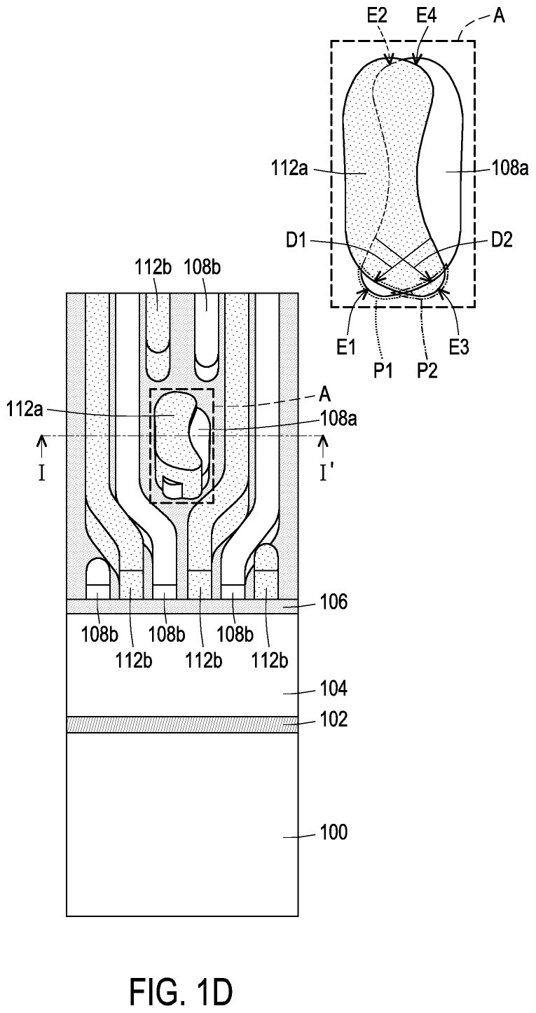

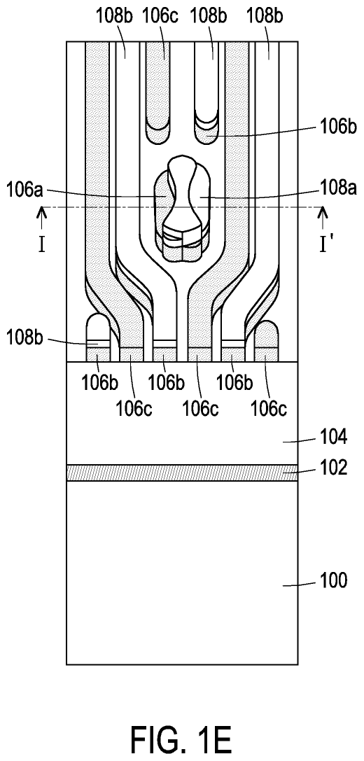

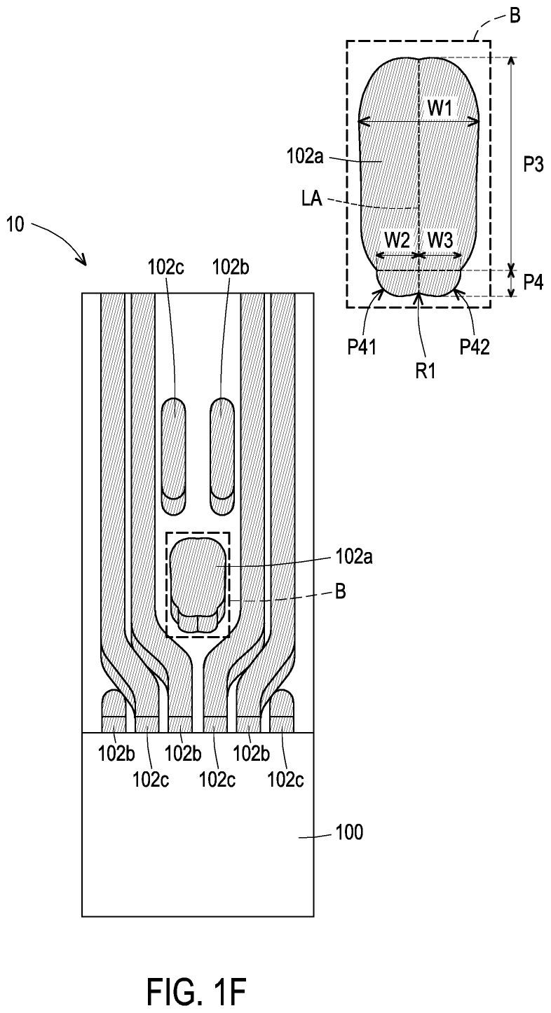

FIG. 1A to FIG. 1F are partial perspective views of a manufacturing method of a semiconductor structure according to some embodiments of the present disclosure. In addition, in FIG. 1D and FIG. 1F, the enlargement of top views of the area A and the area B are shown.

Referring to FIG. 1A, a substrate 100 is provided. The substrate 100 may be a semiconductor substrate, such as a silicon substrate. Moreover, although not shown in the figure, required components (such as active components, dielectric layers, interconnect structures or combinations thereof) may be formed on the substrate 100.

Next, the material layer 102 is formed on the substrate 100. In this embodiment, the material layer 102 may be a layer to be patterned. The material layer 102 can be a single-layer structure or a multi-layer structure. The material of the material layer 102 may be conductive material, dielectric material or semiconductor material. In some embodiments, the material layer 102 is formed by chemical vapor deposition (CVD) or physical vapor deposition (PVD). In this embodiment, the material of the material layer 102 is an example of a conductive material, but the disclosure is not limited thereto. In some embodiments, the conductive material is, for example, tungsten, titanium, titanium nitride or combinations thereof. Next, a hard mask layer 104 may be formed on the material layer 102. The hard mask layer 104 may be a single-layer structure or a multi-layer structure. In some embodiments, the material of the hard mask layer 104 is, for example, a highly selective and transparent film (HST), silicon nitride, spin on carbon (SOC), silicon oxynitride or a combination thereof. The forming method of the hard mask layer 104 is, for example, CVD, spin coating or a combination thereof.

A hard mask layer 106 may then be formed over the material layer 102. In some embodiments, the hard mask layer 106 may be formed on hard mask layer 104. The material of the hard mask layer 106 is, for example, silicon oxide. The forming method of the hard mask layer 106 is, for example, CVD.

Next, a hard mask layer 108 may be formed on the material layer 102. In some embodiments, the hard mask layer 108 may be formed on hard mask layer 106. The material of the hard mask layer 108 is, for example, polysilicon. The forming method of the hard mask layer 108 is, for example, CVD.

Moreover, a patterned photoresist layer 110 may be formed on the hard mask layer 108. The patterned photoresist layer 110 may expose a portion of the hard mask layer 108. In some embodiments, the patterned photoresist layer 110 may be formed by a photolithography process.

Referring to FIG. 1B, the hard mask layer 108 may be patterned by using the patterned photoresist layer 110 as a mask to form a hard mask pattern 108a. In this way, the hard mask pattern 108a may be formed on the material layer 102. In some embodiments, the hard mask pattern 108a may be formed on the hard mask layer 106. The material of the hard mask pattern 108a is, for example, polysilicon. The hard mask pattern 108a may also be referred to as the first exploded pattern of LELE.

In this embodiment, one hard mask pattern 108a is taken as an example, but the present disclosure is not limited thereto. In some other embodiments, the number of hard mask patterns 108a may be more than one.

In some embodiments, during the process of forming the hard mask pattern 108a, the hard mask pattern 108b may be formed simultaneously. For example, the patterned photoresist layer 110 may be used as a mask to remove part of the hard mask layer 108 to pattern the hard mask layer 108, and to form the hard mask pattern 108a and the hard mask pattern 108b. In some embodiments, removing part of the hard mask layer 108 can use, for example, dry etching.

The hard mask pattern 108a and the hard mask pattern 108b may be separated from each other. In some embodiments, the top-view pattern of the hard mask pattern 108b may be striped. In some embodiments, the material of the hard mask pattern 108b is, for example, polysilicon.

In this embodiment, the number of hard mask patterns 108b may be multiple, but the disclosure is not limited thereto. In some embodiments, the plurality of hard mask patterns 108b may have the same or different shapes and/or sizes. In addition, those skilled in the art may adjust the shape and/or size of the hard mask pattern 108b according to product requirements.

Next, the patterned photoresist layer 110 may be removed, for example, by a dry stripping method or a wet stripping method.

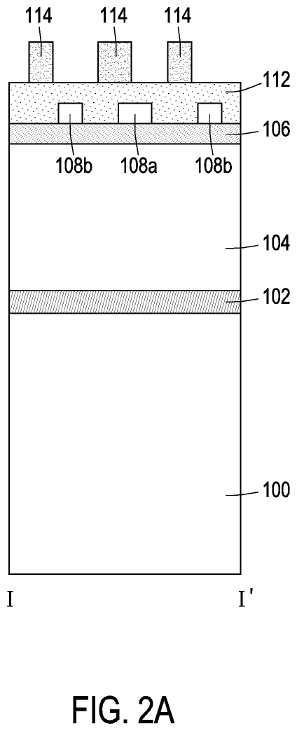

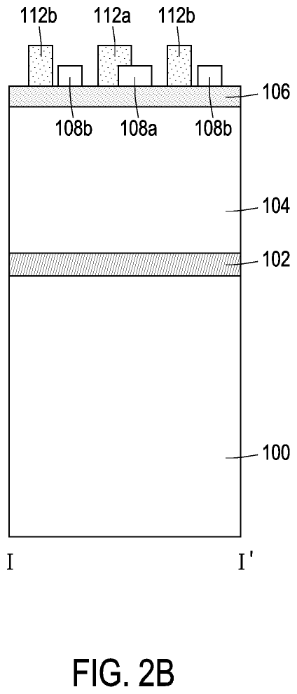

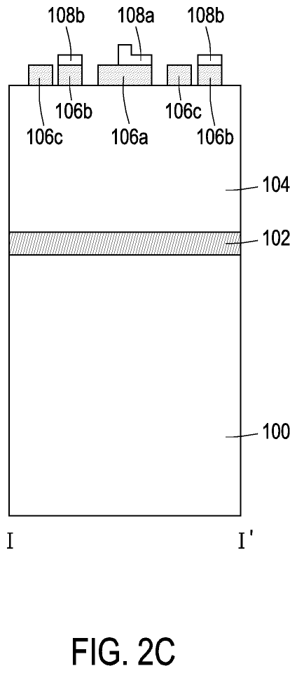

Referring to FIG. 1C and FIG. 2A, a hard mask layer 112 may be formed on the hard mask pattern 108a. In some embodiments, the hard mask layer 112 may further be formed on the hard mask pattern 108b. The hard mask layer 112 may be a single-layer structure or a multi-layer structure. In some embodiments, the material of the hard mask layer 112 is, for example, spin-on-carbon (SOC), spin-on-silicon anti-reflection coating (SOSA), or a combination thereof. A method for forming the hard mask layer 112 is, for example, a spin coating method.

Next, a patterned photoresist layer 114 may be formed on the hard mask layer 112. The patterned photoresist layer 114 may expose a portion of the hard mask layer 112. The patterned photoresist layer 114 may be formed through a photolithography process.

Referring to FIG. 1D and FIG. 2B, the hard mask layer 112 may be patterned by using the patterned photoresist layer 114 as a mask to form a hard mask pattern 112a. In this way, the hard mask pattern 112a may be formed on the hard mask pattern 108a. The top-view pattern of the hard mask pattern 112a partially overlaps the top-view pattern of the hard mask pattern 108a. The hard mask pattern 112a may also be referred to as a second exploded pattern of LELE.

In some embodiments, the top-view pattern of the hard mask pattern 108a may have an end portion E1 and an end portion E2, and the top-view pattern of the hard mask pattern 112a may have an end portion E3 and an end portion E4. The end portion E1 of the hard mask pattern 108a may be adjacent to the end portion E3 of the hard mask pattern 112a, and the end portion E2 of the hard mask pattern 108a may be adjacent to the end portion E4 of the hard mask pattern 112a.

In some embodiments, the top-view pattern of the hard mask pattern 108a partially overlaps the top-view pattern of the hard mask pattern 112a, and the end portion E1 of the hard mask pattern 108a may be bent toward the top-view pattern of the hard mask pattern 112a. In the meantime, the end portion E1 may cross the contour of the top-view pattern of the hard mask pattern 112a in the width direction D1 of the top-view pattern of the hard mask pattern 112a such that the terminal end P1 of the end portion E1 does not overlap with the hard mask pattern 112a. In this way, it is possible to increase the overlapping area of the top-view pattern of the hard mask pattern 108a and the top-view pattern of the hard mask pattern 112a, thereby preventing the target pattern 102a from having a concave contour as described in the related art. In addition, since the terminal end P1 of the end portion E1 of the hard mask pattern 108a does not overlap with the hard mask pattern 112a, the overlay window between the hard mask pattern 108a and the hard mask pattern 112a may be increased.

In some embodiments, the end portion E3 of the top-view pattern of the hard mask pattern 112a may be bent toward the top-view pattern of the hard mask pattern 108a. In the meantime, the end portion E3 may cross the contour of the top-view pattern of the hard mask pattern 108a in the width direction D2 of the top-view pattern of the hard mask pattern 108a such that the terminal end P2 of the end portion E3 does not overlap with the hard mask pattern 108a. In this way, it is possible to increase the overlapping area of the top-view pattern of the hard mask pattern 112a and the top-view pattern of the hard mask pattern 108a, thereby preventing the target pattern 102a from having a concave contour as described in the related art. In addition, since the terminal end P2 of the end portion E3 of the hard mask pattern 112a does not overlap with the hard mask pattern 108a, the overlay window between the hard mask pattern 108a and the hard mask pattern 112a may be increased.

In this embodiment, the hard mask pattern 108a and the hard mask pattern 112a may have the above features simultaneously, but the disclosure is not limited thereto. As long as at least one of the hard mask pattern 108a and the hard mask pattern 112a has the above-mentioned features (that is, the end portion of one exploded pattern is able to cross the contour of the top-view pattern of the other exploded pattern in the width direction of the top-view pattern of the other exploded pattern, such that the terminal end of the end portion of one exploded pattern does not overlap with another exploded pattern), either one of them falls within the scope of the present disclosure.

In other embodiments, the hard mask pattern 108a may have the aforementioned features, and the hard mask pattern 112a may not have the aforementioned features. That is, the end portion E1 of the hard mask pattern 108a may be bent toward the top-view pattern of the hard mask pattern 112a. In the meantime, the end portion E1 may cross the contour of the top-view pattern of the hard mask pattern 112a in the width direction D1 of the top-view pattern of the hard mask pattern 112a. The end portion E1 may have a non-overlapping portion P1, the end portion E3 of the hard mask pattern 112a may not be bent toward the top-view pattern of the hard mask pattern 108a, and the end portion E3 may not cross the contour of the top-view pattern of the hard mask pattern 108a in the width direction D2 of the top-view pattern of the hard mask pattern 108a, and the end portion E3 may not have the non-overlapping portion P2.

In other embodiments, the hard mask pattern 108a may not have the aforementioned features, and the hard mask pattern 112a may have the aforementioned features. That is, the end portion E1 of the hard mask pattern 108a may not bend toward the top-view pattern of the hard mask pattern 112a, and the end portion E1 may not cross the contour of the top-view pattern of the hard mask pattern 112a in the width direction D1 of the top-view pattern of the hard mask pattern 112a. The end portion E1 may not have the non-overlapping portion P1, the end portion E3 of the hard mask pattern 112a may be bent toward the top-view pattern of the hard mask pattern 108a. The end portion E3 may cross the contour of the top-view pattern of the hard mask pattern 108a in the width direction D2 of the top-view pattern of the hard mask pattern 108a, and the end portion E3 may have a non-overlapping portion P2.

In some embodiments, the end portion E2 of the top-view pattern of the hard mask pattern 108a may be bent toward the top-view pattern of the hard mask pattern 112a. In this way, the overlapping area of the top-view pattern of the hard mask pattern 108a and the top-view pattern of the hard mask pattern 112a may be increased, thereby preventing deformation of the subsequently formed target pattern 102a (see FIG. 1F), so that the target pattern 102a meets the expectation. In some other embodiments, the end portion E2 of the top-view pattern of the hard mask pattern 108a may not bend toward the top-view pattern of the hard mask pattern 112a.

In some embodiments, the end portion E4 of the top-view pattern of the hard mask pattern 112a may be bent toward the top-view pattern of the hard mask pattern 108a. In this way, the overlapping area of the top-view pattern of the hard mask pattern 112a and the top-view pattern of the hard mask pattern 108a may be increased, thereby preventing deformation of the subsequently formed target pattern 102a (see FIG. 1F), so that the target pattern 102a meets the expectation. In some other embodiments, the end portion E4 of the top-view pattern of the hard mask pattern 112a may not bend toward the top-view pattern of the hard mask pattern 108a.

In other embodiments, when the environment where the end portion E2 of the hard mask pattern 108a is located is the same as the environment where the end portion E1 of the hard mask pattern 108a is located (for example, an environment with a higher pattern density), the end portion E2 of the top-view pattern of the hard mask pattern 108a may be bent toward the top-view pattern of the hard mask pattern 112a, and the end portion E2 may cross the contour of the top-view pattern of the hard mask pattern 112a in the width direction of the top-view pattern of the hard mask pattern 112a, so that the terminal end of the end portion E2 does not overlap with the hard mask pattern 112a (not shown).

In other embodiments, when the environment where the end portion E4 of the hard mask pattern 112a is located is the same as the environment where the end portion E3 of the hard mask pattern 112a is located (for example, an environment with a higher pattern density), the end portion E4 of the top-view pattern of the hard mask pattern 112a may be bent toward the top-view pattern of the hard mask pattern 108a, and the end portion E4 may cross the contour of the top-view pattern of the hard mask pattern 108a in the width direction of the top-view pattern of the hard mask pattern 108a, such that the terminal end of the end portion E4 does not overlap with the hard mask pattern 108a (not shown).

In some embodiments, during the process of forming the hard mask pattern 112a, the hard mask pattern 112b may be formed simultaneously. For example, the patterned photoresist layer 114 may be used as a mask to remove part of the hard mask layer 112 to pattern the hard mask layer 112, so as to form the hard mask pattern 112a and the hard mask pattern 112b. In some embodiments, removing part of the hard mask layer 112 can use, for example, dry etching.

The hard mask pattern 112a and the hard mask pattern 112b may be separated from each other. In some embodiments, the hard mask pattern 112b and the hard mask pattern 108a may be separated from each other. In some embodiments, the hard mask pattern 112b and the hard mask pattern 108b may be separated from each other. In some embodiments, the top-view pattern of the hard mask pattern 112b may be in the shape of stripes.

Next, the patterned photoresist layer 114 may be removed, for example, by a dry stripping method or a wet stripping method.

Referring to FIG. 1E and FIG. 2C, the pattern of the hard mask pattern 108a and the pattern of the hard mask pattern 112a may be transferred to the hard mask layer 106 to form the hard mask pattern 106a. The top-view pattern of the hard mask pattern 106a may correspond to the top-view pattern formed by superimposing the top-view pattern of the hard mask pattern 108a and the top-view pattern of the hard mask pattern 112a. In some embodiments, the material of the hard mask pattern 106a is, for example, silicon oxide. In this embodiment, the number of the hard mask pattern 106a is exemplified as one, but the disclosure is not limited thereto. In some other embodiments, the number of hard mask patterns 106a may be multiple.

In some embodiments, the patterns of the hard mask pattern 108b and the hard mask pattern 112b may be transferred to the hard mask layer 106 to form the hard mask pattern 106b corresponding to the hard mask pattern 108b and the hard mask pattern 106c corresponding to the hard mask pattern 112b. In some embodiments, during the process of forming the hard mask pattern 106a, the hard mask pattern 106b and the hard mask pattern 106c may be formed simultaneously. For example, the hard mask layer 106 may be patterned by using the hard mask pattern 108a, the hard mask pattern 112a, the hard mask pattern 108b, and the hard mask pattern 112b as masks to remove part of the hard mask layer 106 by, for example, dry etching, so as to form a hard mask pattern 106a, a hard mask pattern 106b, and a hard mask pattern 106c.

The hard mask pattern 106a, the hard mask pattern 106b, and the hard mask pattern 106c may be separated from each other.

In some embodiments, during the process of transferring the patterns of the hard mask pattern 108a and the hard mask pattern 112a to the hard mask layer 106, part of the hard mask pattern 108a may be removed, such that the cross-sectional shape of the hard mask pattern 108a may include a stepped shape. In some embodiments, during the process of transferring the pattern of the hard mask pattern 108b to the hard mask layer 106, part of the hard mask pattern 108b may be removed to reduce the height of the hard mask pattern 108b.

In some embodiments, after forming the hard mask pattern 106a, the hard mask pattern 112a may be removed. In some embodiments, the hard mask pattern 112b may be removed after the hard mask pattern 106c is formed. In some embodiments, the hard mask pattern 112a and the hard mask pattern 112b may be removed simultaneously through the same process, for example, a dry etching process.

Referring to FIG. 1F, the pattern of the hard mask pattern 106a may be transferred to the material layer 102 to form the semiconductor structure 10 with the target pattern 102a. The top-view pattern of the target pattern 102a may correspond to the top-view pattern of the hard mask pattern 106a. With the method of this embodiment, the pattern of the hard mask pattern 108a and the pattern of the hard mask pattern 112a may be transferred to the material layer 102 through LELE technology, so as to form the target pattern 102a. The top-view pattern of the target pattern 102a may correspond to the top-view pattern formed by superimposing the top-view pattern of the hard mask pattern 108a and the top-view pattern of the hard mask pattern 112a.

In some embodiments, when the material of the target pattern 102a is a conductive material, the target pattern 102a may be used as a contact pad (e.g., a landing pad), but the disclosure is not limited thereto.

In some embodiments, the patterns of the hard mask patterns 106b and 106c may be transferred to the material layer 102 to form a target pattern 102b corresponding to the hard mask pattern 106b and a target pattern 102c corresponding to the hard mask pattern 106c. In some embodiments, during the process of forming the target pattern 102a, the target pattern 102b and the target pattern 102c may be formed simultaneously. For example, the hard mask layer 104 and the material layer 102 may be patterned by using the hard mask patterns 108a, 106a, 108b, 106b, and 106c as masks to remove part of the hard mask layer 104 and part of the material layer 102, and the target patterns 102a, 102b and 102c are formed. In some embodiments, removing part of the hard mask layer 104 and part of the material layer 102 can use, for example, dry etching. In some embodiments, during the process of forming target patterns 102a, 102b, and 102c, the hard mask patterns 108a, 106a, 108b, 106b, 106c and 104 may be removed.

In some embodiments, when the material of the target pattern 102b and the target pattern 102c are conductive materials, the target pattern 102b and the target pattern 102c may be used as wires, but the disclosure is not limited thereto.

In this embodiment, the pattern of the hard mask pattern 108a, the pattern of the hard mask pattern 112a, the pattern of the hard mask pattern 108b and the pattern of the hard mask pattern 112b may be transferred to the hard mask layer 106, the hard mask layer 104 and the material layer 102 through an etching process (e.g., dry etching), but the disclosure is not limited thereto. In other embodiments, part of the layers described in the above embodiments may be omitted according to requirements. For example, the hard mask layer 104 may be omitted, and the pattern of the hard mask pattern 108a, the pattern of the hard mask pattern 112a, the pattern of the hard mask pattern 108b, and the pattern of the hard mask pattern 112b may be transferred to the hard mask layer 106 and the material layer 102 through an etching process. In other embodiments, the hard mask layer 104 and the hard mask layer 106 may be omitted, and the pattern of the hard mask pattern 108a, the pattern of the hard mask pattern 112a, the pattern of the hard mask pattern 108b and the pattern of the hard mask pattern 112b may be transferred to the material layer 102 through an etching process.

Hereinafter, the semiconductor structure 10 in the above-mentioned embodiment will be described with reference to FIG. 1F. In addition, although the method for forming the semiconductor structure 10 is described by taking the above method as an example, the present disclosure is not limited thereto.

Referring to FIG. 1F, the semiconductor structure 10 includes a substrate 100 and a target pattern 102a. The target pattern 102a is disposed on the substrate 100. The top-view pattern of the target pattern 102a includes a main portion P3 and a protruding portion P4. The main portion P3 and the protruding portion P4 are connected to each other along the long axis LA of the top-view pattern of the target pattern 102a.

The protruding portion P4 includes a first portion P41 on one side of the long axis LA. The maximum width W2 of the first portion P41 perpendicular to the long axis LA is less than half of the maximum width W1 of the main portion P3. In some embodiments, the protruding portion P4 may include a second portion P42 on the other side of long axis LA. The second portion P42 may be connected to the first portion P41. In some embodiments, the maximum width W3 of the second portion P42 perpendicular to the long axis LA may be less than half of the maximum width W1 of the main portion P3. In this embodiment, the protruding portion P4 may include a first portion P41 and a second portion P42, but the disclosure is not limited thereto. As long as the protruding portion P4 includes at least one of the first portion P41 and the second portion P42, such protruding portion P4 falls within the scope of the present disclosure. In some embodiments, the contour of the protruding portion P4 may have a recess R1. The extension of the long axis LA may pass through the recess R1. In some embodiments, the recess R1 may be recessed toward the main portion P3.

In this embodiment, one end of the target pattern 102a has a protruding portion P4, but the present disclosure is not limited thereto. In some other embodiments, two opposite ends of the target pattern 102a may have the protruding portion P4.

In addition, the semiconductor structure 10 may further include at least one of the target pattern 102b and the target pattern 102c. The target pattern 102b and the target pattern 102c are disposed on the substrate. The target pattern 102a, the target pattern 102b and the target pattern 102c may be separated from each other. In addition, the details of various components in the semiconductor structure 10 (e.g., materials and formation methods) have been described thoroughly in the above-mentioned embodiments, and will not be further described here.

Based on the above embodiments, it can be seen that in the semiconductor structure 10 and its manufacturing method, the top-view pattern of the target pattern 102a includes a main portion P3 and a protruding portion P4, and the main portion P3 and the protruding portion P4 are connected to each other along the long axis LA of the top-view pattern of the target pattern 102a. The protruding portion P4 includes a first portion P41 located on one side of the long axis LA, and the maximum width W2 of the first portion P41 perpendicular to the long axis LA is less than half of the maximum width W1 of the main portion P3. Therefore, through the structural design of the target pattern 102a, it is possible to prevent the target pattern 102a from having a concave contour as described in the related art, so the process window of the subsequent process (e.g., contact via process) may be improved.

The semiconductor structure according to an embodiment of the present disclosure may be used as a wire or a dummy pattern, such as a wire or a bit line in a DRAM, but the disclosure is not limited thereto. When using the LELE process to make the wires, a pattern that needs to be miniaturized may be generated according to an embodiment of the present disclosure, so as to increase the process tolerance of the contact pad. According to an embodiment of the present disclosure, the semiconductor structure according to an embodiment of the present disclosure may be used to make bit lines and back-stage metal wires, or to make dummy patterns for adjusting the pattern density of the LELE process.

The present disclosure is suitable for making miniaturized semiconductor structures to increase the total number of crystal grains on a wafer. Therefore, the present disclosure may reduce the production cost and energy consumption of manufacturing a single IC, and reduce the production energy consumption of subsequent packaging, thereby reducing carbon emissions in the production process of semiconductor structures. Furthermore, the present disclosure provides a green semiconductor technology with the improved reliability and durability of the semiconductor structure of the present disclosure.

Although the present disclosure has been disclosed above with the embodiments, it is not intended to limit the present disclosure. Those with ordinary knowledge in the technical field may make some modifications and changes without departing from the spirit and scope of the present disclosure. Therefore, the scope to be protected by the present disclosure should be defined by the scope of appended claims.

What is claimed is:

1. A semiconductor structure, comprising:
a substrate; and
a target pattern, which is disposed on the substrate, wherein a top-view pattern of the target pattern comprises a main portion and a protruding portion, the main portion and the protruding portion are connected with each other along a long axis of the top-view pattern of the target pattern, the protruding portion is connected to the main portion, the protruding portion comprises a first portion located on one side of the long axis, and a maximum width of the first portion perpendicular to the long axis is less than half of a maximum width of the main portion.

2. The semiconductor structure according to claim 1, wherein the protruding portion comprises a second portion on the other side of the long axis, and the second portion is connected to the first portion.

3. The semiconductor structure according to claim 2, wherein a maximum width of the second portion perpendicular to the long axis is less than half of the maximum width of the main portion.

4. The semiconductor structure according claim 2, wherein a contour of the protruding portion has a recess, and an extension of the long axis passes through the recess.

5. The semiconductor structure according to claim 4, wherein the recess is recessed toward the main portion.

6. A manufacturing method of a semiconductor structure, comprising:
providing a substrate;
forming a material layer on the substrate;
forming a first hard mask pattern on the material layer;
forming a second hard mask pattern on the first hard mask pattern, wherein a top-view pattern of the second hard mask pattern partially overlaps a top-view pattern of the first hard mask pattern; and
transferring a pattern of the first hard mask pattern and a pattern of the second hard mask pattern to the material layer to form a target pattern, wherein a top-view pattern of the target pattern comprises a main portion and a protruding portion, the main portion and the protruding portion are connected to each other along a long axis of the top-view pattern of the target pattern, the protruding portion is connected to the main portion, the protruding portion comprises a first portion on one side of the long axis, and a maximum width of the first portion perpendicular to the long axis is less than half of a maximum width of the main portion.

7. The manufacturing method of the semiconductor structure according to claim 6, wherein the top-view pattern of the target pattern corresponds to a top-view pattern formed by superimposing the top-view pattern of the first hard mask pattern and the top-view pattern of the second hard mask pattern.

8. The manufacturing method of the semiconductor structure according to claim 6, wherein a first end portion of the top-view pattern of the first hard mask pattern is bent toward the top-view pattern of the second hard mask pattern, and the first end portion crosses a contour of the top-view pattern of the second hard mask pattern in a width direction of the top-view pattern of the second hard mask pattern such that a terminal end of the first end portion does not overlap with the second hard mask pattern.

9. The manufacturing method of the semiconductor structure according to claim 8, wherein a second end portion of the top-view pattern of the first hard mask pattern is bent toward the top-view pattern of the second hard mask pattern.

10. The manufacturing method of the semiconductor structure according to claim 6, wherein a first end portion of the top-view pattern of the second hard mask pattern is bent toward the top-view pattern of the first hard mask pattern, and the first end portion crosses a contour of the top-view pattern of the first hard mask pattern in a width direction of the top-view pattern of the first hard mask pattern, such that a terminal end of the first end portion does not overlap with the first hard mask pattern.

11. The manufacturing method of the semiconductor structure according to claim 10, wherein a second end portion of the top-view pattern of the second hard mask pattern is bent toward the top-view pattern of the first hard mask pattern.

12. The manufacturing method of the semiconductor structure according to claim 10, wherein the protruding portion comprises a second portion on the other side of the long axis, and the second portion is connected to the first portion.

13. The manufacturing method of the semiconductor structure according to claim 12, wherein a first end portion of the top-view pattern of the first hard mask pattern is bent toward the top-view pattern of the second hard mask pattern, and the first end portion crosses a contour of the top-view pattern of the second hard mask pattern in a width direction of the top-view pattern of the second hard mask pattern such that a terminal end of the first end portion does not overlap with the second hard mask pattern, and
a second end portion of the top-view pattern of the second hard mask pattern is bent toward the top-view pattern of the first hard mask pattern, and the second end portion crosses a contour of the top-view pattern of the first hard mask pattern in a width direction of the top-view pattern of the first hard mask pattern such that a terminal end of the second end portion does not overlap with the first hard mask pattern.

14. The manufacturing method of the semiconductor structure according to claim 6, wherein the method for forming the first hard mask pattern comprises:
forming a hard mask layer on the material layer;
forming a patterned photoresist layer on the hard mask layer; and
using the patterned photoresist layer as a mask to pattern the hard mask layer, thereby forming the first hard mask pattern.

15. The manufacturing method of the semiconductor structure according to claim 6, wherein the method for forming the second hard mask pattern comprises:
forming a hard mask layer on the first hard mask pattern;
forming a patterned photoresist layer on the hard mask layer; and
using the patterned photoresist layer as a mask to pattern the hard mask layer, thereby forming the second hard mask pattern.

16. The manufacturing method of the semiconductor structure according to claim 6, further comprising:
forming a hard mask layer on the material layer prior to forming the first hard mask pattern.

17. The manufacturing method of the semiconductor structure according to claim 16, wherein the method of transferring a pattern of the first hard mask pattern and a pattern of the second hard mask pattern to the material layer comprises:
transferring the pattern of the first hard mask pattern and the pattern of the second hard mask pattern to the hard mask layer to form a third hard mask pattern; and
transferring a pattern of the third hard mask pattern to the material layer to form the target pattern.

18. The manufacturing method of the semiconductor structure according to claim 17, wherein a top-view pattern of the third hard mask pattern corresponds to a top-view pattern formed by superimposing the top-view pattern of the first hard mask pattern and the top-view pattern of the second hard mask pattern.

19. The manufacturing method of the semiconductor structure according to claim 17, wherein in the process of transferring the pattern of the first hard mask pattern and the pattern of the second hard mask pattern to the hard mask layer, a part of the first hard mask pattern is removed, so that a cross-sectional shape of the first hard mask pattern comprises a stepped shape.

20. The manufacturing method of the semiconductor structure according to claim 17, further comprising:
after forming the third hard mask pattern, the second hard mask pattern is removed.
